(19) United States
(12) Patent Application Publication
(10) Pub. No.: US 2012/0306549 A1
(43) Pub. Date: Dec. 6, 2012

(54) SEMICONDUCTOR INTEGRATED CIRCUIT

(75) Inventor: Shigeru Nagatomo, Miyazaki (JP)

(73) Assignee: LAPIS SEMICONDUCTOR CO., LTD., TOKYO (JP)

(21) Appl. No.: 13/483,529

(22) Filed: May 30, 2012

(30) Foreign Application Priority Data
Jun. 2, 2011 (JP) 2011-124445

(51) Int. Cl. H03L 7/00

(52) U.S. Cl. 327/143

(57) ABSTRACT

A semiconductor integrated circuit includes a constant current circuit and a start-up circuit. The constant current circuit includes a first current mirror circuit including a first and second transistors; and a second current mirror circuit including a third transistor connected to a first node and a fourth transistor connected to a second node. The start-up circuit includes a fifth transistor that supplies start-up current to the constant current circuit via the second node; a sixth transistor that uses a potential of the first node as a control voltage; a seventh transistor that is connected to a third node into which current from the sixth transistor flows and that has a diode-connected configuration; a capacitor connected to a fourth node into which current from the seventh transistor flows; and a latch circuit that controls the fifth based on a potential of the fourth node.

### CROSS-REFERENCE TO RELATED APPLICATION

This application is based on and claims priority under 35 USC 119 from Japanese Patent Application No. 2011-124445 filed on Jun. 2, 2011, the disclosure of which is incorporated by reference herein.

### BACKGROUND

1. Technical Field

The present invention pertains to a semiconductor integrated circuit and particularly relates to a semiconductor integrated circuit that starts up a constant current circuit.

2. Related Art

A semiconductor integrated circuit equipped with a circuit that starts up a constant current circuit has been proposed which, as illustrated in FIG. 4, includes a constant current circuit 112 and a start-up circuit 114. The constant current circuit 112 includes a first current mirror circuit 101′ configured by two first electrically conductive transistors (P-channel MOS transistors) M1′ and M2′ and a second current mirror circuit 102′ configured by two electrically conductive transistors (N-channel MOS transistors) M3′ and M4′. The semiconductor integrated circuit illustrated in FIG. 4 is a configuration that addresses a problem of not being able to supply a start-up current to the constant current circuit and not being able to start up the constant current circuit when the rise of the power supply voltage is slow in a case in which transistors whose threshold voltages Vt are low are used as the transistors configuring the current mirror circuits.

That is, in the semiconductor integrated circuit illustrated in FIG. 4, a transistor M5′ is switched on (becomes conductive) before a capacitor C1′ is charged, and the on-current of the transistor M5′ is used as the start-up current and is supplied to the constant current circuit 112 to start up the constant current circuit 112. After start-up, a node N4′ is charged to the power supply voltage level, the transistor M5′ becomes non-conductive, and the constant current circuit 112 stabilizes at a predetermined operating point. Here, by using a transistor whose threshold voltage Vt is high as a transistor M7′, in a case in which the rise of the power supply is slow, an increase in the potential of the node N4′ resulting from leak current at a time when the temperature is high is prevented, while the gate-source voltage (Vgs) of the transistor M5′ exceeds the threshold voltage Vt during that time, and the start-up current is supplied to the constant current circuit 112.

However, in the conventional semiconductor integrated circuit described above, in a case in which the rise of the power supply is slow, charging is performed, with respect to the capacitor C1′ having one terminal connected to the node N4′, by current in the sub-threshold region (also called the weak inversion region) of the transistor M7′, that is, the capacitor C1′ is charged by current flowing between the source and drain even if the gate voltage of the transistor M7′ is equal to or less than the threshold voltage Vt. As a result, as indicated by the long dashed double-short dashed line in FIG. 5 for example, the node N4′ has a potential that increases because of the charging even though its inclination differs with respect to the rise of the power supply voltage VDD. In FIG. 5, the potential obtained by subtracting the potential V_{N4} of the node N4′ from VDD (VDD V_{N4}) between point A and point B is the gate-source voltage Vgs of the transistor M5′. Consequently, a potential difference of V_{N4} arises between the gate-source voltage Vgs of the transistor M5′ (referred to as Vgs5) and the gate-source voltage Vgs of the transistor M7′ (referred to as Vgs7).

It is known that the drain current in the weak inversion region of the transistor M7′ has the characteristic that it increases exponentially with respect to an increase in the gate-source voltage Vgs. For that reason, the difference between the gate-source voltage Vgs7 of the transistor M7′ (=VDD) and the gate-source voltage Vgs5 of the transistor M5′ (=VDD−V_{N4}) is important with respect to the application of the start-up current of the constant current circuit. The period of application of the start-up current of the conventional constant current circuit described above is a period from when the rise of the power supply voltage VDD exceeds point A (the point when the constant current circuit starts operating) in FIG. 5 to until the power supply voltage VDD exceeds the threshold voltage Vt of the transistor M7′ and the node N4′ is charged to the potential of the power supply voltage VDD by the drain current in the strong inversion region. Supply of the start-up current is complete when this period elapses. Consequently, since the gate-source voltage Vgs5 of the transistor M5′ depends on the potential V_{N4} of the node N4′ in the conventional current circuit described above, it is not clear whether or not the gate-source voltage Vgs5 of the transistor M5′, compared to the gate-source voltage Vgs7 of the transistor M7′, has reached the voltage Vgs that passes the start-up current of the constant current circuit between the period of point A to point B.

Further, since the start-up current stops at a voltage of VDD exceeding the threshold voltage Vt of the transistor M7′ in the conventional constant current circuit, it is not clear whether or not the start-up current has been supplied sufficiently to the constant current circuit and the constant current circuit is in a stable operating state. Moreover, it is necessary for VDD when the start-up current flows into the constant current circuit to be a potential at which the transistor M4′ of the constant current circuit enters the operating point (potential at which the constant current circuit can operate) and which can hold current, but the start-up current cannot be passed to the constant current circuit in a stable state in which the transistor M4′ can operate.

### SUMMARY

The present invention has been proposed in consideration of the above and provides a semiconductor integrated circuit that may start up a constant current circuit more stably and may reliably operate in normal state the constant current circuit after start-up.

One aspect of the present invention is a semiconductor integrated circuit including: a constant current circuit including: a first current mirror circuit including a first transistor and a second transistor; and a second current mirror circuit including a third transistor that is connected to a first node into which current from the first transistor flows, and including a fourth transistor that is connected to a second node into which current from the second transistor flows; and a start-up circuit including: a fifth transistor that supplies start-up current to the constant current circuit via the second node; a sixth transistor that uses a potential of the first node as a control voltage; a seventh transistor that is connected to a third node into which current from the sixth transistor flows and that has a diode-connected configuration; a capacitor that is connected to a fourth node into which current from the seventh transistor flows; and a latch circuit that drives and controls the fifth transistor in accordance with an increase in a potential of the fourth node.

According to this aspect, the transistors of the constant current circuit may be operated in a stable state to start up the constant current circuit, and the constant current circuit after start-up may be operated reliably.

### BRIEF DESCRIPTION OF THE DRAWINGS

An exemplary embodiment of the present invention will be described in detail based on the following figures, wherein:

FIG. 1 is a circuit diagram illustrating the configuration of a semiconductor integrated circuit pertaining to the embodiment;

FIG. 2 is a drawing schematically illustrating a change in voltage during power-up of the semiconductor integrated circuit pertaining to the embodiment;

FIG. 3A and FIG. 3B are drawings for describing an inverter configuring a latch circuit of the semiconductor integrated circuit pertaining to the embodiment;

FIG. 4 is a circuit diagram illustrating the configuration of a conventional semiconductor integrated circuit; and

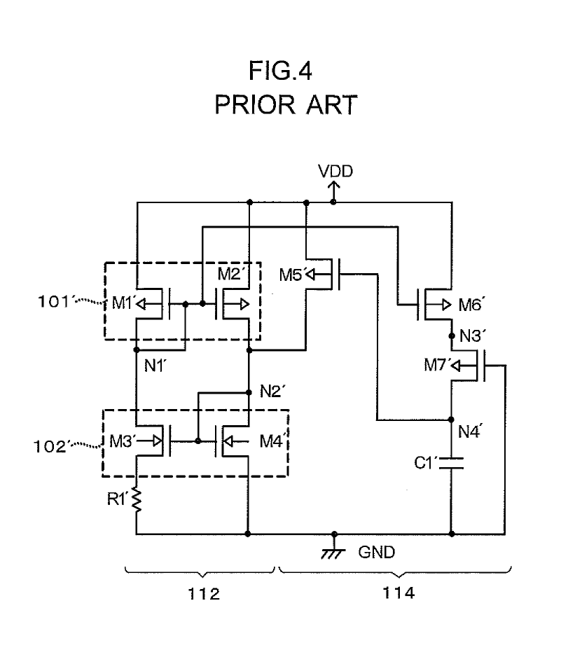

FIG. 5 is a drawing schematically illustrating a change in voltage during power-up of the conventional semiconductor integrated circuit.

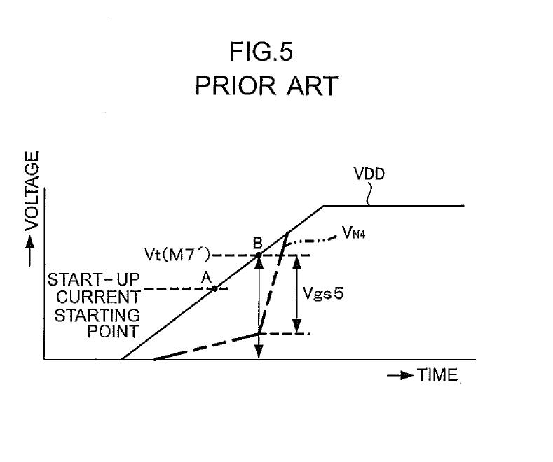

### DETAILED DESCRIPTION

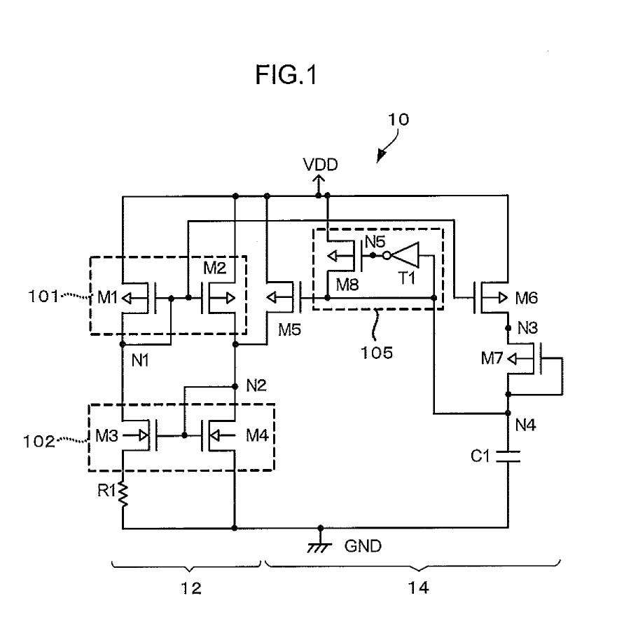

FIG. 1 is a circuit diagram illustrating the configuration of a semiconductor integrated circuit 10 pertaining to an embodiment of the present invention. As illustrated in FIG. 1, the semiconductor integrated circuit 10 is equipped with a constant current circuit 12 and a start-up circuit 14. The start-up circuit 14 includes a latch circuit 105 that will be described below. Further, a power supply voltage VDD (hereinafter also called a first voltage) of 1 V, for example, and a ground voltage GND (hereinafter also called a second voltage) that is lower than the first voltage are supplied by an unillustrated power supply to the semiconductor integrated circuit 10.

The constant current circuit 12 includes a first current mirror circuit 101, a second current mirror circuit 102, and a resistor R1. The first current mirror circuit 101 is configured by two first electrically conductive transistors (e.g., P-channel MOS transistors) M1 and M2. The P-channel MOS transistors M1 and M2 are configured by gate electrodes G (called control electrodes), source electrodes S (called first electrodes), and drain electrodes D (called second electrodes). The gate electrodes G of the transistor M1 and the transistor M2 are interconnected, and the gate electrode G and the drain electrode D of the transistor M1 are connected (shorted). The drain electrode D of the transistor M1 is connected to a first node N1, and the drain electrode D of the transistor M2 is connected to a second node N2. The power supply voltage VDD that is the first voltage is supplied to the source electrodes S of the transistor M1 and the transistor M2.

The first current mirror circuit 101 becomes non-conductive when a voltage of the first voltage level is supplied to the interconnected gate electrodes G of the transistor M1 and the transistor M2 and becomes conductive when a voltage of the second voltage level is supplied.

The second current mirror circuit 102 is configured by two second electrically conductive transistors (e.g., N-channel MOS transistors) M3 and M4. The N-channel MOS transistors M3 and M4 are configured by gate electrodes G (called control electrodes), source electrodes S (called first electrodes), and drain electrodes D (called second electrodes). The gate electrodes G of the transistor M3 and the transistor M4 are interconnected. The source electrode S of the transistor M3 is connected to one terminal of the resistor R1, and the drain electrode D of the transistor M3 is connected to the first node N1. The gate electrode G and the drain electrode D of the transistor M4 are connected (shorted). The drain electrode D of the transistor M4 is connected to the second node N2, and the ground voltage GND that is lower than the first voltage is supplied to the source electrode S of the transistor M4.

The second voltage—that is, the ground voltage GND—is supplied to the other terminal of the resistor R1. The current flowing in the first node N1 and the second node N2 is determined by the current gain of the second current mirror circuit 102 and depends on the resistor R1. The second current mirror circuit 102 becomes conductive when a voltage of the first voltage level is supplied to the interconnected gate electrodes G of the transistor M3 and the transistor M4 and becomes non-conductive when a voltage of the second voltage level is supplied.

The start-up circuit 14 is configured by a P-channel MOS transistor M5, a P-channel MOS transistor M6, a P-channel MOS transistor 7 whose gate electrode G and drain electrode D are connected (shorted), a capacitor C1, and the latch circuit 105. The gate electrode of the transistor M7 and one terminal of the capacitor C1 are connected to a node N4, and the ground voltage GND (the second voltage) is supplied to the other terminal of the capacitor C1.

The latch circuit 105 is configured by an inverter T1 and a P-channel MOS transistor M8. The input end of the inverter T1 is connected to the node N4, and the output end of the inverter T1 and the gate terminal G of the transistor M8 are connected via a node N5. The drain electrode D of the transistor M8 is connected to the gate electrode G of the transistor M5 and is also connected to the input end of the inverter T1. The threshold voltage Vt of the transistor M8 is set to the same value as the threshold voltage Vt of the transistor M7. Further, the threshold voltage of the inverter T1 is set in such a way that the inverter T1 recognizes it as a logical “L” (Low) when the power supply voltage VDD of the transistor M7 has risen to the same potential as the threshold voltage Vt.

The drain electrode D of the transistor M5 is connected to the node N2. The gate electrode of the transistor M6 is connected to the gate electrodes G (which are also the node N1) of the transistor M1 and the transistor M2 configuring the first current mirror circuit 101, so that the transistor M1 and the transistor M6 configure a current mirror circuit. The power supply voltage VDD is supplied to the source electrode S of the transistor M6, and the drain electrode D of the transistor M6 is connected to a node N3. The source electrode S of the transistor M7 is connected to the node N3, and the drain electrode D of the transistor M7 is connected to the node N4. The transistors M5 and M6 become non-conductive when a voltage of the first voltage level is supplied to their gate electrodes G as a control voltage, and become conductive when a voltage of the second voltage level is supplied to their gate electrodes G.

The threshold voltages Vt of the transistors configuring the semiconductor integrated circuit 10 are set such that the transistors M7 and M8 have threshold voltages Vt that are larger than the threshold voltages Vt of the transistors M1, M2, M5, and M6, and that the transistors M7 and M8 have threshold voltages Vt that are larger in absolute value than the threshold voltages Vt of the transistors M3 and M4. For example, the threshold voltages Vt of the transistors M1, M2, etc. may be 0.5 V, and the threshold voltages Vt of the transistors M7 and M8 may be 0.9 V.

Next, the operation of the semiconductor integrated circuit 10 of the present embodiment will be described. During power-up of the semiconductor integrated circuit 10, the voltage level of the node N1 is substantially that of the power supply voltage VDD (the first voltage level), and since a voltage of the same potential as that of the node N1 is supplied to the gate electrode G of the transistor M6, the transistor M6 is in a non-conductive state. Further, the node N2 has a voltage level of substantially the ground voltage GND (the second voltage level), and the node N4 is at a voltage level of substantially the ground voltage GND. Thus, the output of the inverter T1 of the latch circuit 105 to which the voltage of the logical “L” level has been inputted will be a logical “H” (High), and the transistor M8 in the latch circuit 105 becomes non-conductive.

As a result, the voltage level of the node N4—that is, a voltage level of substantially the ground voltage GND—is supplied as a control voltage to the gate electrode G of the transistor M5. Therefore, the transistor MS becomes conductive and current flows to the node N2 via the transistor M5. Because of this, the voltage level of the node N2 rises, and the transistor M3 and the transistor M4 of the second current mirror circuit 102 become conductive.

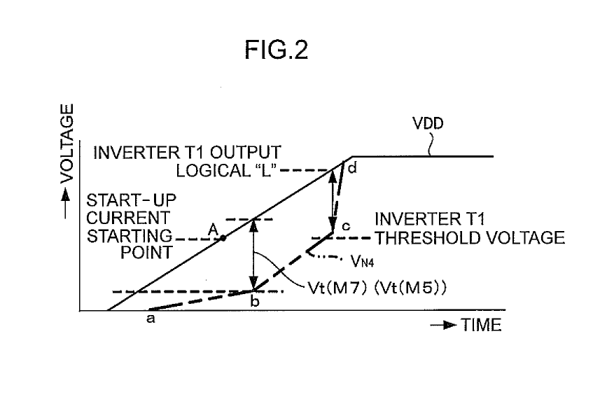

As the transistors M3 and M4 being in a conductive state, current flows to the node N1 and the voltage level of the node N1 falls. When the voltage level of the node N1 falls to the level of the ground voltage GND, the transistor M1 and the transistor M2 of the first current mirror circuit 101 become conductive. Thus, current flows to the node N1 via the transistor M1, and current flows to the node N2 via the transistor M2. At this time, the transistor M6 is in a non-conductive state, but the capacitor C1 is charged by the current in the sub-threshold region of the transistor M6 (leak current flowing between the source and drain when the gate voltage of the transistor M6 is equal to or less than the threshold voltage Vt) and the sub-threshold current flowing out from the transistor M7. As a result, the voltage level of the node N4 gradually rises as indicated by line segment a-b in FIG. 2.

Meanwhile, the voltage level applied to the gate electrode G of the transistor M6 of the start-up circuit 14 also falls because of the drop in the voltage level of the node N1. When the voltage level of the node N1 falls to the ground voltage GND, the transistor M6 becomes conductive, current flows to the node N4 via the transistor M6 and the transistor M7 that is diode-connected, and the electric charge stored in the capacitor C1 gradually increases because of that current. That is, in accompaniment with the rise in the power supply voltage VDD, the voltage level of the drain electrode D of the transistor M7 that is diode-connected rises following the power supply voltage VDD while remaining dropped by the threshold voltage Vt of the transistor M7 from the power supply voltage VDD as indicated by line segment b-c in FIG. 2 for example. This is because the gate-source voltage (Vgs) of the transistor M7 does not exceed the threshold voltage Vt because the transistor M7 is diode-connected. Therefore, the gate-source voltage Vgs of the transistor M5 (written as Vgs5) and the gate-source voltage of the transistor M7 Vgs (written as Vgs7) become structurally the same, and the gate-source voltage Vgs5 also rises with the potential remaining lower by a constant value than the rise in the power supply voltage VDD. Thus, the on-current (start-up current) of the transistor MS is larger than the on-current of the transistor M7.

Because of the charging of the capacitor C1, when the potential of the node N4 rises until the inverter T1 of the latch circuit 105 recognizes the potential of the node N4 as the logical “H” (point c in FIG. 2), the output of the inverter T1 inverts from the logical “H” to the logical “L”. The transistor M8 in the latch circuit 105 receives the inverted voltage of the inverter T1 and becomes conductive. As a result, the potential of the node N4 and the power supply voltage VDD match (point d in FIG. 2), the transistor M5 of the start-up circuit 14 becomes non-conductive, and supply of the start-up current with respect to the constant current circuit 12 is complete. Even though the transistor M5 becomes non-conductive, current is already flowing to the node N1 and the node N2, so the constant current circuit 12 will stably operate.

Given that gm1, gm2, gm3, and gm4 represent the mutual conductance gin of the transistors M1, M2, M3, and M4, respectively, the current I1 flowing through the node N1 and the current 12 flowing through the node N2 are expressed as follows:

I1=k*T/q*{1n(gm1*gm2/gm3*gm4)}

I2=gm2/gm1*I1

where k is the Boltzmann constant, T is absolute temperature, q is electron charge quantity, and * is a multiplication symbol.

Next, the function of the latch circuit 105 provided in the start-up circuit 14 will be described. During the period in which the capacitor C1 is being charged, current flows into the capacitor C1, whereby the node N4 has a potential remaining lower by the threshold voltage Vt of the transistor M7 than that of the power supply voltage VDD as described above. If the latch circuit 105 is not provided in the start-up circuit 14, since the potential level of the node N4 is substantially the power supply voltage VDD in a state in which charging of the capacitor C1 has been complete, for example, when the source potential VSS (here, the ground voltage GND) fluctuates, the potential fluctuation travels to the node N4 via the capacitor C1. The transistor M7 is difficult to absorb the potential fluctuation with respect to the power supply voltage VDD since the gate-source voltage Vgs of the transistor M7 is small. As a result, the voltage level of the gate electrode G of the transistor M5 drops from the power supply voltage VDD, and the transistor M5 that should be in a non-conductive state becomes conductive and unexpected current flows into the constant current circuit 12.

However, in the semiconductor integrated circuit 10 pertaining to the present embodiment which includes the latch circuit 105, even if the potential of the node N4 rises with the potential remaining lower by the threshold voltage Vt of the transistor M7 than that of the power supply voltage VDD, the output of the inverter T1 becomes the logical “L” at the time when the input level of the inverter T1 of the latch circuit 105 disposed in the start-up circuit 14 is recognized as the logical “H” with respect to the level of the rising power supply voltage VDD, and the transistor M8 in the latch circuit 105 strongly maintains the potential of the node N4 at the level of the power supply voltage VDD. As a result, even if there is a fluctuation in the source potential VSS or the like, the voltage level of the gate electrode G of the transistor M5 does not drop from the power supply voltage VDD, the non-conductive state of the transistor M5 is maintained, and the constant current circuit 12 may be operated in a normal state.

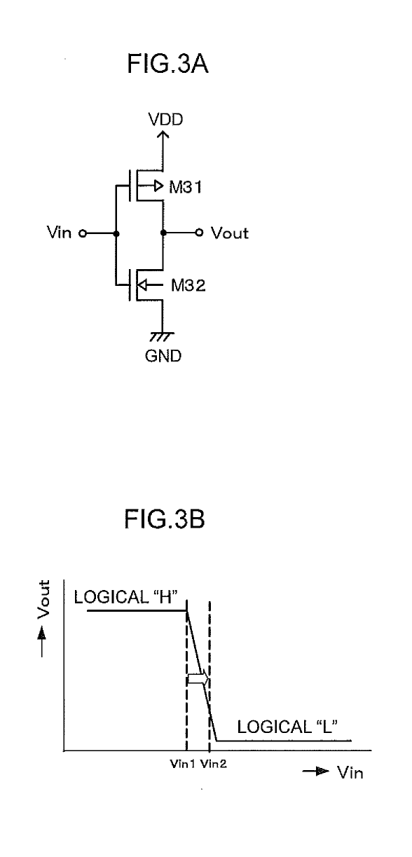

Further, as illustrated in FIG. 3A for example, the inverter T1 of the latch circuit 105 is configured by connecting the drain electrode D of a P-channel MOS transistor M31 to the drain electrode D of an N-channel MOS transistor M32. The power supply voltage VDD is supplied to the source electrode S of the transistor M31, and the ground voltage GND is supplied to the source electrode S of the transistor M32. The gate electrodes G of the transistors M31 and M32 are interconnected, and this point of connection being used as the input terminal of the inverter T1 and the interconnected drain electrodes D being used as the output terminal of the inverter T1.

FIG. 3B illustrates the input/output characteristic of the inverter T1 illustrated in FIG. 3A. The input voltage (Vin) input to the interconnected gate electrodes G of the transistors M31 and M32 and the output voltage (Vout) from the interconnected drain electrodes D have a relationship in which their logical values (logical “H” and logical “L”) are inverted from each other. Here, the threshold voltage Vt31 of the transistor M31 is set lower than the threshold voltage Vt32 of the transistor M32, or, the mutual conductance gm31 of the transistor M31 is set higher than the mutual conductance gm32 of the transistor M32. In this way, the input voltage (Vin) that the inverter T1 recognizes as the logical “H” is raised. That is, by raising the input voltage with which the output voltage of the inverter T1 becomes the logical “L” (by changing Vin1 to Vin2 as illustrated in FIG. 3B), the range of the output that becomes the logical “H” of the inverter T1 is expanded. Here, during power-up of the semiconductor integrated circuit 10, the inverter T1 is set to recognize that potential as the logical “L” when the power supply voltage VDD of the transistor M7 has risen to the same potential as the threshold voltage Vt.

As described above, the semiconductor integrated circuit pertaining to the present embodiment applies a control voltage of a start-up transistor that supplies a start-up current to a constant current circuit, which is a voltage that rises following a power supply voltage VDD while being dropped from the power supply voltage VDD by a threshold voltage Vt of a transistor that is diode-connected, and the semiconductor integrated circuit supplies the start-up current from the start-up transistor to the constant current circuit. Further, when the voltage applied to the start-up transistor has risen up to a level which a latch circuit including an inverter and a transistor recognizes it as the logical “H”, the output from the inverter is inverted from the logical “H” to the logical “L.” In this way, the rise in the control voltage applied to the start-up transistor that supplies the start-up current to the constant current circuit is delayed, and the start-up transistor may be avoided from being in a non-conductive state before supplying a sufficient start-up current to the constant current circuit.

Further, by inverting the inverter output to the logical “L” when the voltage applied to the start-up transistor has risen until it is recognized as the logical “H” by the latch circuit, and using the output of the transistor in the latch circuit that has switched on because of that as the control voltage of the start-up transistor that supplies the start-up current to the constant current circuit, the control voltage applied to the start-up transistor is strongly held at the level of the power supply voltage VDD by the transistor in the latch circuit so that the non-conductive state of the start-up transistor is maintained, and unnecessary current may be prevented from flowing into the constant current circuit so that the constant current circuit may be operated reliably in a normal state.

Moreover, by setting the threshold voltage Vt of the transistor M8 configuring the latch circuit 105 to be the same as the threshold voltage Vt of the transistor M7 that is diode-connected, the high-temperature leak current and the sub-threshold current of the transistor M8 may be made smaller compared to those of the transistor M7.

In the semiconductor integrated circuit pertaining to the above embodiment, an example has been described in which the on-current of the transistor M5 is made larger than the on-current of the transistor M7 by setting the threshold voltage Vt of the P-channel MOS transistor M7 higher than the threshold voltage Vt of the P-channel MOS transistor M5, but embodiments are not limited to this. For example, the on-current of the transistor M5 may also be made larger than the on-current of the transistor M7 by making the mutual conductance gm7 of the P-channel MOS transistor M7 smaller than the mutual conductance gm5 of the P-channel MOS transistor M5.

Further, the capacitor C1 connected to the node N4 in the semiconductor integrated circuit pertaining to the above embodiment has been described as an element built into the semiconductor integrated circuit. However, embodiments are not limited to this and the capacitor C1 may also be a capacitor that is externally connectable to an outside terminal disposed in correspondence to the node N4 and the ground voltage GND. By making the capacitor C1 externally connectable, it is possible to lengthen the delay time of the potential rise in the node N4 by changing the capacitance of the capacitor C1 to various values (e.g., by changing a capacitance of several picofarads to several microfarads).

Moreover, the start-up circuit 14 of the semiconductor integrated circuit 10 pertaining to the above embodiment may also be given a configuration in which, instead of the capacitor C1, a resistor is connected to the node N4 and the rising voltage resulting from the current flowing in that resistor is inputted to the latch circuit 105 to control the transistor M5.

What is claimed is:

1. A semiconductor integrated circuit comprising:
a constant current circuit including
a first current mirror circuit including a first transistor and a second transistor, and
a second current mirror circuit that includes a third transistor connected to a first node into which current from the first transistor flows, and a fourth transistor connected to a second node into which current from the second transistor flows; and
a start-up circuit including
a fifth transistor that supplies start-up current to the constant current circuit via the second node,
a sixth transistor that uses a potential of the first node as a control voltage,
a seventh transistor that is connected to a third node into which current from the sixth transistor flows and that has a diode-connected configuration,
a capacitor that is connected to a fourth node into which current from the seventh transistor flows, and
a latch circuit that controls the fifth transistor in accordance with an increase in a potential of the fourth node.

2. The semiconductor integrated circuit according to claim 1, wherein:
the latch circuit comprises:
an inverter including an input end having a potential that is the potential of the fourth node; and
an eighth transistor that uses a potential of an output end of the inverter as a control voltage; and
when the potential of the fourth node reaches a predetermined potential and the eighth transistor becomes conductive, the latch circuit stops the supply of the start-up current from the fifth transistor to the constant current circuit.

3. The semiconductor integrated circuit according to claim 2, wherein the potential of the fourth node increases with the potential remaining lower than a power supply voltage by an amount that is a threshold voltage of the seventh transistor, and when the inverter recognizes the potential of the fourth node input to the inverter as a first logical value, the inverter outputs a second logical value that is opposite to the first logical value and the eighth transistor becomes conductive, whereby the fifth transistor is maintained in a non-conductive state and the potential of the fourth node is held at the power supply voltage.

4. The semiconductor integrated circuit according to claim 1, wherein absolute values of threshold voltages of the seventh transistor and the eighth transistor are set higher than absolute values of threshold voltages of the first transistor, the second transistor, the third transistor, the fourth transistor, the fifth transistor, and the sixth transistor.

5. The semiconductor integrated circuit according to claim 4, wherein the threshold voltages of the seventh transistor and the eighth transistor are set so as to be equal to each other.

6. The semiconductor integrated circuit according to claim 5, wherein:
the inverter is configured by interconnecting drain electrodes of a ninth transistor and a tenth transistor and by interconnecting gate electrodes of the ninth transistor and the tenth transistor; and
a threshold voltage of the ninth transistor is set lower than a threshold voltage of the tenth transistor or a mutual conductance of the ninth transistor is set higher than a mutual conductance of the tenth transistor.
